(19) United States
(12) Patent Application Publication
(10) Pub. No.: US 2018/0088211 A1
(43) Pub. Date: Mar. 29, 2018

(54) INTEGRATED RADIATION HARDENED RADIO FREQUENCY DIGITIZER AND SIGNAL PROCESSING ELECTRONICS

(71) Applicant: U.S.A. as represented by the Administrator of the National Aeronautics and Space Administration, Washington, DC (US)

(72) Inventors: NATHANIEL A. GILL, Ellicott city, MD (US); ROBERT W. MOSS, University Park, MD (US); DAVID J. PETRICK, Severna Park, MD (US)

(21) Appl. No.: 15/280,011

(22) Filed: Sep. 29, 2016

(51) Int. Cl. G01S 7/28; G01S 17/10; G01S 7/285; G01S 7/486; H03B 5/32; H03L 7/08; H03K 19/003

(52) U.S. Cl. CPC G01S 7/2806; G01S 17/10; G01S 7/285; H03K 19/0033; H03B 5/32; H03L 7/08; G01S 7/4861

(57) ABSTRACT

Aspects of the present disclosure involve a system and method for sampling received signals for performing time of flight estimation using LiDAR signal processing. In one aspect, a radio frequency analog-to-digital converter is used for real time waveform digitalization. The radio frequency analog-to-digital converter may be coupled to a mezzanine card and used to generate a clock for the converter. The digital waveform may then be buffered and correlated for time of flight estimation.

### TECHNICAL FIELD

This disclosure relates generally to LiDAR signal processing, and more specifically to a method for digitizing laser pulses using LiDAR signal processing.

### BACKGROUND

Light Detection and Ranging (LiDAR) is a remote sensing technology that uses light pulses to measure ranges or distances of an object. It is a technology that has application in various fields including archeology, meteorology, bathymetry, etc. Further, the information extracted from these measurements can have many uses, including determining surface characteristics, creating elevation models, and even obtaining three-dimensional (3-D) images of an object at a distance. To determine the 3-D image of an object at a distance, differences (or time of flight estimations) are determined between the time transmission of laser light pulses and the reception of the sampled reflected signals. Generally, conventional components used in sampling and determining these time of flight estimations can be slow, inaccurate, or too large to provide the real time capabilities required in applications like space exploration and military surveillance.

### BRIEF SUMMARY

The present disclosure is directed to an apparatus and methods for performing time of flight estimation. The apparatus includes a synthesizing card electrically coupled to an analog-to-digital converter, the synthesizing card transmitting a clock signal to the analog-to-digital converter for synchronizing the analog-to-digital converter. The apparatus can further include a receiver for receiving a plurality of radio frequency pulses, where each radio frequency pulse is digitized into an in-phase and quadrature sample at a clock edge of the clock signal at the analog-to-digital converter. The apparatus includes a buffer for storing each in-phase and quadrature sample digitized by the analog-to-digital converter. In addition, the apparatus includes at least one correlator electrically coupled to the buffer to determine a time of flight of each of the in-phase and quadrature samples.

The method can include transmitting a clock signal by a synchronizing card, to an analog-to-digital converter for synchronizing the analog-to-digital converter. The method can also include receiving, by a receiver, a plurality of radio frequency pulses, where each of the radio frequency pulse is digitized into an in-phase and quadrature sample at a clock edge of the clock signal at the analog-to-digital converter. The method can include storing, by a buffer, each in-phase and quadrature sample digitized by the analog-to-digital converter and retrieving and determining, by a correlator, a time of flight of each of the in-phase and quadrature samples.

The apparatus can also include a non-transitory machine readable medium having stored thereon machine-readable instructions executable to cause a machine to perform operations including transmitting a clock signal to an analog-to-digital converter for synchronizing the analog-to-digital converter. The medium can further execute instructions to perform receiving, by a receiver, a plurality of radio frequency pulses, where each radio frequency pulse is digitized into an in-phase and quadrature sample at a clock edge of the clock signal at the analog-to-digital converter. Also, the medium can include instructions causing the machine to execute instructions including storing, by a buffer, each in-phase and quadrature sample digitized by the analog-to-digital converter. The medium can also include a machine readable medium for retrieving and determining, by a correlator, a time of flight of each of the in-phase and quadrature samples.

### BRIEF DESCRIPTION OF THE DRAWINGS

The description will be more fully understood with reference to the following figures and charts, which are presented as various embodiments of the disclosure and should not be construed as a complete recitation of the scope of the disclosure, wherein:

FIG. 1 is a diagram illustrating an example system architecture.

FIG. 2 is a block diagram illustrating a system for digitizing laser pulses using LiDAR signal processing.

FIG. 3 is a flow chart of a method digitizing laser pulses using LiDAR signal processing.

### DETAILED DESCRIPTION

Aspects of the present disclosure involve systems, methods, devices and the like for sampling received signals for performing time of flight estimation using LiDAR signal processing. In one aspect, a radio frequency analog-to-digital converter is used for real time waveform digitalization. The radio frequency analog-to-digital converter may be coupled to a mezzanine card and used to generate a clock for the converter. In some instances, the mezzanine card may use oscillators and a synthesizer to generate a clock signal that is used for sampling the received signals. The sampled signals may be stored in a buffer and correlated for time of flight estimation. The correlation may occur using numerous correlators running in parallel with the number of correlators varying based on the desired speed of the system.

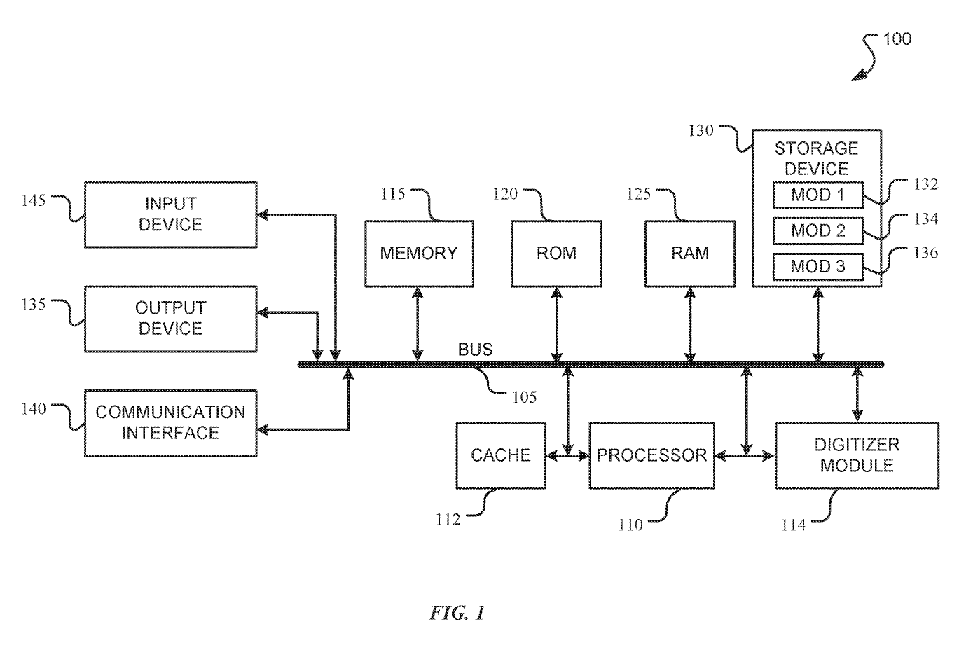

FIG. 1 is a diagram of an architecture 100 for digitizing a waveform. Conventionally, radio interferometry architectures include radio frequency components which can be high powered components. The components can generate noise and heat which can lead to unreliable and/or unstable measurements. To overcome the heat and instability, a high rate digital-to-analog converter is introduced which can provide better signal stability for digitizing the incoming pulse.

FIG. 1 introduces the general architectural components for a system that can be used in performing LiDAR signal processing. FIG. 1 discloses some basic hardware components that can apply to system examples of the present disclosure. An exemplary system and/or computing device 100 is introduced that includes a processing unit (CPU or processor) 110 and a system bus 105 that couples various system components, including the system memory 115, read only memory (ROM) 120, and random access memory (RAM) 125 to the processor 110. The system 100 can include a cache 112 of high-speed memory connected directly with, in close proximity to, or integrated as part of the processor 110. The system 100 copies data from the memory 115/120/125 and/or the storage device 130 to the cache 112 for quick access by the processor 110. In this way, the cache provides a performance boost that avoids processor 110 delays while waiting for data These and other modules can control or be configured to control the processor 110 in the performance of various operations or actions. Other system memory 115 may be available for use as well. The memory 115 can include multiple different types of memory with different performance characteristics. It can be appreciated that the disclosure may operate on a computing device 100 with more than one processor 110 or on a group or cluster of computing devices networked together to provide greater processing capability. The processor 110 can include any general purpose processor and a hardware module or software module, such as module 1 132, module 2 134, and module 3 136, stored in storage device 130, or standalone light detection and ranging (LiDAR) processing module 114 configured to control the processor 110 as well as a special-purpose processor where software instructions are incorporated into the processor. The processor 110 may be a self-contained computing system, containing multiple cores or processors, a bus, a memory controller, a cache, etc. A multi-core processor may be symmetric or asymmetric. The processor 110 can include multiple processors, such as a system having multiple, physically separate processors in different sockets, or a system having multiple processor cores on a single physical chip. Similarly, the processor 110 can include multiple distributed processors located in multiple separate computing devices, but working together such as via a communications network. Multiple processors or processor cores can share resources such as memory 115 or cache 112, or can operate using independent resources. The processor 110 can include one or more of a state machine, an application specific integrated circuit (ASIC), or a programmable gate array (PGA) including a field PGA.

The system bus 105 may he any of several types of bus structures, including a memory bus or memory controller, a peripheral bus, and a local bus using any of a variety of bus architectures. A basic input/output (BIOS) stored in ROM 120 or the like may provide a basic routine that helps to transfer information between elements within the computing device 100, such as during start-up. The computing device 100 further includes storage devices 130 or computer-readable storage media such as a hard disk drive, a magnetic disk drive, an optical disk drive, a tape drive, a solid-state drive, a RAM drive, a removable storage device, a redundant array of inexpensive disks (RAID), a hybrid storage device, or the like. The storage device 130 is connected to the system bus 105 by a drive interface. The drives and the associated computer-readable storage devices provide nonvolatile storage of computer-readable instructions, data structures, program modules, and other data for the computing device 100. In one aspect, a hardware module that performs a particular function includes the software component stored in a tangible computer-readable storage device in connection with the necessary hardware components, such as the processor 110, bus 105, display (or any output device) 135, and so forth, to carry out a particular function. In another aspect, the system can use a processor and a computer-readable storage device to store instructions which, when executed by the processor, cause the processor to perform operations, a method or other specific actions. The basic components and appropriate variations can be modified depending on the type of device, such as whether the device 100 is a small, handheld computing device, a desktop computer, or a computer server. When the processor 110 executes instructions to perform “operations,” the processor 110 can perform the operations directly and/or facilitate, direct, or cooperate with another device or component to perform the operations.

Although the exemplary embodiment(s) described herein employs the hard disk 130, other types of computer-readable storage devices which can store data that are accessible by a computer, such as magnetic cassettes, flash memory cards, digital versatile disks (DVDs), cartridges, random access memories (RAMS) 125, read only memory (ROM) 120, a cable containing a bit stream and the like, may also be used in the exemplary operating environment. According to this disclosure, tangible computer-readable storage media, computer-readable storage devices, computer-readable storage media, and computer-readable memory devices expressly exclude media such as transitory waves, energy, carrier signals, electromagnetic waves, and signals per se.

To enable user interaction with the computing device 100, an input device 145 can be any number of input mechanisms, such as a microphone for speech, a touch-sensitive screen for gesture or graphical input, a keyboard, a mouse, a motion input speech and so forth. An output device 135 can also be one or more of a number of output mechanisms known to those of skill in the art. In some instances, multimodal systems enable a user to provide multiple types of input to communicate with the computing device 100. The communications interface 140 generally governs and manages the user input and system output. There is no restriction on operating on any particular hardware arrangement, and therefore the basic hardware depicted may easily be substituted for improved hardware or firmware arrangements as they are developed.

For clarity of explanation, the illustrative system embodiment is presented as including individual functional blocks, including functional blocks labeled as a “processor” or processor 110. The functions of these blocks may be provided through the use of either shared or dedicated hardware, including, but not limited to, hardware capable of executing software and hardware, such as a processor 110, that is purpose-built to operate as an equivalent to software executing on a general purpose processor. For example, the functions of one or more processors presented in FIG. 1 can be provided by a single shared processor or multiple processors (use of the term “processor” should not be construed to refer exclusively to hardware capable of executing software). Illustrative embodiments may include microprocessor and/or digital signal processor (DSP) hardware, read-only memory (ROM) 120 for storing software performing the operations described below, and random access memory (RAM) 125 for storing results. Very large scale integration (VLSI) hardware embodiments, as well as custom VLSI circuitry in combination with a general purpose DSP circuit, may also be provided.

The logical operations of the various embodiments are implemented as: (1) a sequence of computer implemented steps, operations, or procedures running on a programmable circuit within a general use computer; (2) a sequence of computer implemented steps, operations, or procedures running on a specific-use programmable circuit; and/or (3) interconnected machine modules or program engines within the programmable circuits. The system 100 shown in FIG. 1 can practice all or part of the recited methods, can be a part of the recited systems, and/or can operate according to instructions in the recited tangible computer-readable storage devices. Such logical operations can be implemented as modules configured to control the processor 110 to perform particular functions according to the programming of the module. For example, FIG. 1 illustrates four modules: Mod1 132, Mod2 134, Mod3 136, and LiDAR processing module 114, which are configured to control the processor 110. These modules may be stored on the storage device 130 and loaded into RAM 125 or memory 115 at runtime or may be stored in other computer-readable memory locations. Alternatively, these modules may be standalone such as an independent breadboard with FPGAs mounted on it, (e.g., LiDAR processing module 114) for controlling the LiDAR signal processing.

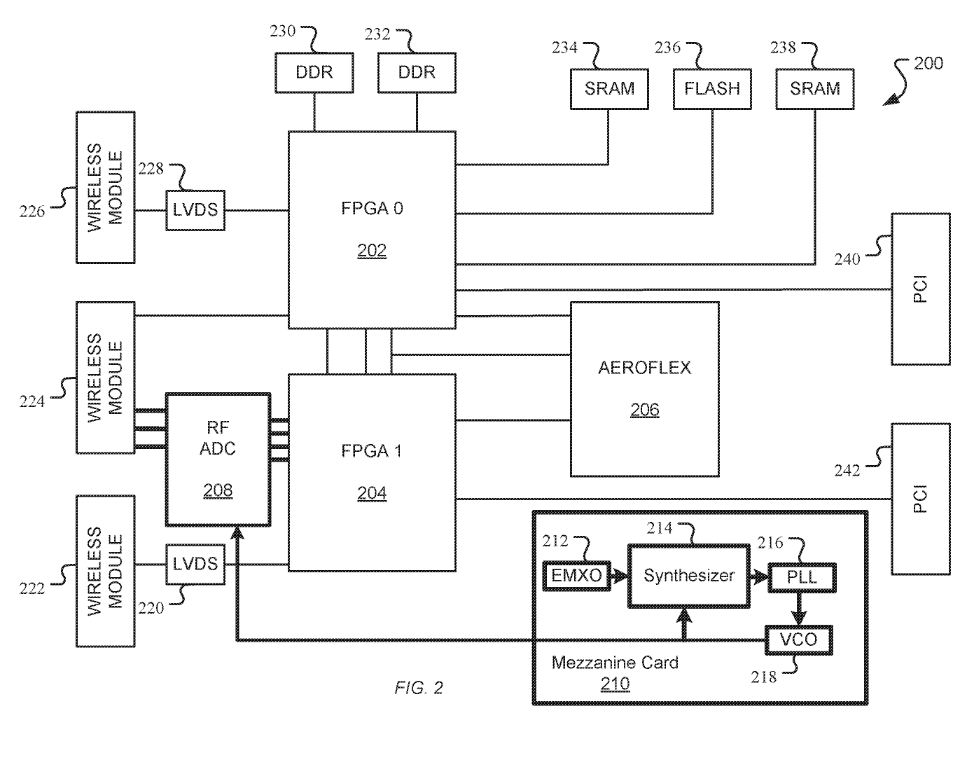

LiDAR processing module 114 can use the computing device 100 of FIG. 1 or similar computer components to perform LiDAR signal processing and correlation. LiDAR processing module 114 can he one or more components as disclosed below and in conjunction with FIG. 2 for sampling the waveforms for time of flight and object image estimation. For example. LiDAR processing module 114 can include field programmable gate arrays (FPGAs), an analog-to-digital converter, a synthesizer, a voltage controlled oscillator (VCO), memory, miniature oscillators, low voltage differential signaling modules, and the like for performing LiDAR signal processing including real time waveform samplig. Additionally or alternatively, LiDAR processing module 114 can independently process or work jointly with processor 110 for determining the time of light of the laser pulses emitted by the laser in order to obtain range and image of an object.

One or more parts of the example computing device 100, up to and including the entire computing device 100, can be virtualized. For example, a virtual processor can be a software object that executes according to a particular instruction set, even when a physical processor of the same type as the virtual processor is unavailable. A virtualization layer or a virtual “host” can enable virtualized components of one or more different computing devices or device types by translating virtualized operations to actual operations. Ultimately however, virtualized hardware of every type is implemented or executed by some underlying physical hardware. Thus, a virtualization compute layer can operate on top of a physical compute layer. The virtualization compute layer can include one or more of a virtual machine, an overlay network, a hypervisor, virtual switching, and any other virtualization application.

The processor 110 can include all types of processors disclosed herein, including a virtual processor. However, when referring to a virtual processor, the processor 110 includes the software components associated with executing the virtual processor in a virtualization layer and the underlying hardware necessary to execute the virtualization layer. The system 100 can include a physical or virtual processor 110 that receives instructions stored in a computer-readable storage device, which can cause the processor 110 to perform certain operations. When referring to a virtual processor 110, the system also includes the underlying physical hardware executing the virtual processor 110.

In some embodiments, the core processing unit in the system can be the Goddard Space Flight Center (GSFC)-developed SpaceCube, a hybrid computing platform designed to provide command and data handling functions for earth-orbiting satellites. The SpaceCube includes five slices (cards): two Power Slices, two Processor Slices, and one Video Control Module (VCM) Slice. Other configurations are possible. Each processor slice contains two Xilinx Virtex Field Programmable Gate Arrays (FPGAs), and each FPGA contains two PPC405 processors running at 250 MHz. These eight processors host multiple instantiations of the system pose application FPose, along with command and telemetry handling software that allows a flight-like ground terminal to control the system remotely. The VCM provides sensor data compression and 16 Gb of flash memory to store raw sensor images for later playback. The Argon SpaceCube is an engineering development unit (EDU) version of the hardware own on the (Relative Navigation Sensor) RNS experiment and Materials International Space Station Experiment.

As indicated, FIG. 1 introduces the general architectural components and specifically the use of LiDAR processing module 114 for LiDAR signal processing to perform waveform sampling and time of flight estimations. FIG. 2 discloses a block diagram of a system 200 for performing such sampling. In some instances, LiDAR signal processing module 114 can perform some or all of the LiDAR signal processing functions/operations described herein. For example, in one embodiment, system 200 can be a standalone component (e.g., breadboard) that includes a bus (e.g., PCI 240, 242) and/or wireless modules 222-226 that connects to other components, processors, breadboards, etc. for receiving reflected signals. In this embodiment, the wireless modules 222-226 can provide the connectivity from the external components to the analog-to-digital converter 208, FPGAs 202-204, memory modules 230-238, external mezzanine card 210, and the like for, sampling the reflected signals and then correlating them for time of flight estimations which can be analyzed to achieve three-dimensional scanning.

As conventionally understood, LiDAR includes the emission of laser pulses of light used to determine the range to a distant object. The distance to the object is determined by measuring the time delay between the emission of the laser pulse of light and the detection of the reflected signal using a correlator. In particular, the time delay can be determined by sampling the reflected signal and comparing against the transmitted pulse which oftentimes comes in the form of an ideal Gaussian pulse. System 200 illustrates some of the modules that can be used to perform both the digitizing and the comparison. As indicated, in one implementation, a LiDAR system may include PCIs 240,242 and wireless modules 222-226 which connect system 200 to external systems, devices, or components. For example, wireless modules 222-226 may be Airbone embedded dual band wireless device server and Ethernet solutions that .support Wi-Fi, Ethernet, and serial communications. Further, the wireless modules may be configured for UART, SPI, Ethernet, GPIO, and 802.11 interfaces.

The wireless modules 222-226 may then be connected to FPGAs 202,204 for processing and/or RF ADC 208 for digitizing the incoming waveforms from the wireless module 224. Generally, ADC modules have been placed external to system 200, however, as illustrated in FIG. 2, system 200 includes the RE ADC 208 for real time sampling. For example, RF ADC 208 may he a digital converter with dual channel, for in-phase and quadrature sampling.

Coupled to the RF ADC 208 may be a mezzanine card 210 that generates the clock for use in sampling/digitizing the received signal by the RF ADC 208. Thus, the mezzanine card 210 may eliminate the need for an external clock as may be necessary by conventional systems. In the current embodiment, the clock is integrated into the system 200 through a connection established between the mezzanine card 210 and the on-board RF ADC 208. For example, the mezzanine card 210 may sit on top of the RF ADC 208 and interface via a connector. As another example, the mezzanine card 210 may reside on the breadboard of system 200. Still in another example, the mezzanine card 210 may reside on a separate system.

The mezzanine card 210 may include an evacuated controlled crystal oscillator (EMXO) 212, a synthesizer 214, a phase-locked loop (PLL) 216, and a voltage controlled oscillator (VCO) 218, which can generate the clock signal used by the RF ADC 208 for synchronizing the RF ADC 208 and sampling the received signal. As an example, a reference oscillator (e.g., EMXO 212) may generate a signal that is fed into a synthesizer 214. The synthesizer is a component that may be used to combine oscillators and filters to generate sounds, shapes, or signals that are desired. Thus, the synthesizer generates the desired signal and that is sent to a phase-locked loop (PLL) 216 which controls the voltage controlled oscillator (VCO) 218, such that the VCO 218 generates the clock that will be used by the RF ADC 208 for digitizing the received waveform in real time.

In particular, the analog-to-digital converter 208 may digitize the waveform into in-phase and quadrature components. The dual channel samples can then be stored in a buffer located in one of the FPGAs 202, 204. In one example, a digital bus may connect the RF ADC 208 to FPGA 204 which receives the digitized signal and stores it in a buffer located in the FPGA 204. In some instances, the digitized signal may be stored in an external buffer or memory module 230-238. Thus, the stored digitized signals may be retrieved and fed into correlators as necessary. Thus, the number of correlators instantiated to perform the time of flight estimations may vary based on the sample rate of the LiDAR system 200. For example, four, sixteen, or sixty correlators may run in parallel based in part on the sampling rate and application of the system 200. The time of flight estimates obtained from the correlators may be used to obtain the range of an object and/or image scan. Thus, system 200 may result in a capable 2 FPGA processor board (e.g., FPGA 0, 1) that can sample two differential RF channels at 1.54 GSPS within 12 bit resolution and process and/or interpret the signals corresponding to the object at a distance in real time.

Note that system 200 is used for exemplary purposes and other modules and configurations may be contemplated. Further, more or less modules may exist in the implementation of the RF ADC 208 and/or mezzanine card 210. For example, in addition to a digital bus coupling the RF ADC 208 to the FPGA 1 204, a low voltage differential signaling bus 220, as well as additional memory components 230-238 may be present for LiDAR processing by the system 200. Additionally, other modules and/or further components can be included in system 200 that are not illustrated in FIG. 2 which are commonly known in the art.

Further, RF ADC 208 along with the other components may be radiation hardened to protect against radiation. For example, in space interferometry, instruments are exposed to an ionizing dose of radiation which decrease instrument reliability and cause the electronics to degrade. In one embodiment, RF ADC 208 is radiation hardened to protect against such radiation. This protection provides the converter with a shield against high energy particles so that single event upsets are mitigated. For example, in this design, the RF ADC 208 may be hardened to 100 kilorads such that the converter reliability is increased and the electronics are protected, In other examples, the RF ADC 208 and other components in system 200 can be hardened to less than 100 kilorads (e.g., 15 kilorads) while others can be hardened to greater than 100 kilorads.

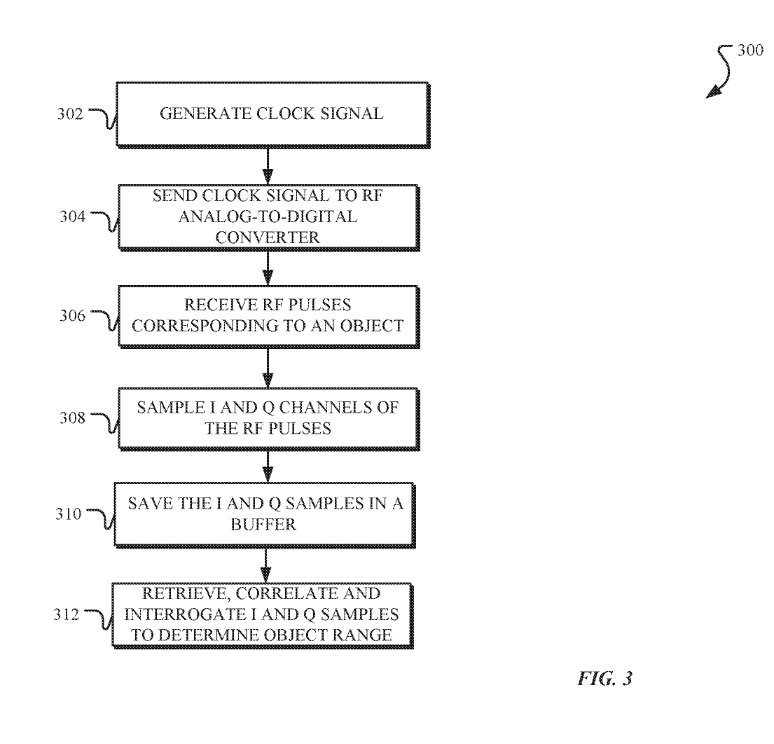

FIG. 3 is a flowchart of the various operations of the presently disclosed technology. Specifically, FIG. 3 is a flow chart of a method for digitizing the received RF pulses for performing time of flight estimation using LiDAR signal processing. Method 300 begins with operation 302, where a mezzanine card starts to generate a continuous clock signal. The clock signal may be generated using numerous modules including oscillators, a phase-locked loop, and a synthesizer. The mezzanine card can be integrated with the system such that no external clock is used. Further, the mezzanine card can couple directly to the RF ADC via a connector or can alternatively reside on the same board as the converter.

Once the clock signal is generated, it is sent, in operation 304, to the RF analog-to-digital converter. The RF ADC then uses the clock signal to sample reflected RF pulses received at a receiver and arriving at the RF ADC for digitizing in operation 306. Photodiodes in the receiver may sense the pulse and transmit them to a front panel of the digitizer (e.g., RF ADC). The received RF pulses may derive from an object at a distance whose range is detected and image scanned. In some embodiments. each RF pulse received may represent a pixel of the object at a distance. Once the RF pulse is received, it is digitized in operation 308. In particular, each pulse is sampled at the rising edge of the in-phase and quadrature (I and Q) channels of the clock. Thus, each pulse is digitized into in-phase and quadrature components and processed over two channels.

Once the received pulse waveform has been digitized, method 300 continues to operation 310, where the I and Q samples are transferred over a digital bus to a buffer for storage. In one embodiment, the I and Q samples are transferred over the digital bus for storage in a buffer within an FPGA. The samples remain stored until the time arrives to retrieve the samples from the buffer in operation 312. The stored samples are recovered for processing including correlating the samples to determine a time of flight estimate. In processing the samples, a specified number of correlators will be instantiated in order to achieve desired sampling rate of the system. That is to say, an appropriate number of correlators will work in parallel such that each correlator processes a pulse (representing a pixel) in order to achieve a desired system sampling rate. At the correlators, the transmitted pulse is correlated with the received reflected pulse in order to determine the time of flight of the signal and the corresponding range of the object.

Note that the LiDAR processing scheme presented in FIGS. 2-3 is a possible example for performing time of flight estimations using LiDAR signal processing that may be employed or be configured in accordance with aspects of the present disclosure. It will be appreciated that other configurations may be utilized.

In the present disclosure, the methods disclosed may be implemented as sets of instructions in hardware or software. It may be further understood that the specific order or hierarchy of steps in the methods disclosed are instances of example approaches. Based upon design preferences, it is understood that the specific order or hierarchy of steps in the method can be rearranged while remaining within the disclosed subject matter. The accompanying method claims present elements of the various steps in a sample order, and are not necessarily meant to be limited to the specific order or hierarchy presented.

While the present disclosure has been described with reference to various implementations, it will be understood that these implementations are illustrative and that the scope of the present disclosure is not limited to them. Many variations, modifications, additions, and improvements are possible. More generally, embodiments in accordance with the present disclosure have been described in the context of particular implementations. Functionality may be separated or combined in blocks differently in various embodiments of the disclosure or described with different terminology. These and other variations, modifications, additions, and improvements may fall within the scope of the disclosure as defined in the claims that follow.

What is claimed is:

1. An apparatus comprising:
a synthesizing card electrically coupled to an analog-to-digital converter, the synthesizing card transmitting a clock signal to the analog-to-digital converter for synchronizing the analog-to-digital converter;
a receiver electrically coupled to the analog-to-digital converter, the receiver receiving a plurality of radio frequency pulses, wherein each radio frequency pulse is digitized into an in-phase and quadrature sample at a clock edge of the clock signal at the analog-to-digital converter;
a buffer coupled to the analog-to-digital converter, the buffer storing each in-phase and quadrature sample digitized by the analog-to-digital converter; and
at least one correlator electrically coupled to the buffer, the at least one correlator determining a time of flight of each of the in-phase and quadrature samples.

2. The apparatus of claim 1, wherein the synthesizing card comprises an oscillator generating a signal that is controlled by a phase-locked loop module.

3. The apparatus of claim 2, wherein the controlled signal generates the clock signal transmitted to the analog-to-digital converter.

4. The apparatus of claim 1, wherein the synthesizing card is integrated into the apparatus including the analog-to-digital converter.

5. The apparatus of claim 1, wherein the plurality of radio frequency pulses correspond to reflected signals from an object at a distance.

6. The apparatus of claim 1, wherein the analog-to-digital converter is hardened to protect against radiation.

7. The apparatus of claim 6, wherein the analog-to-digital converter is hardened to 100 kilorads.

8. An method comprising:
transmitting, by a synthesizing card, a clock signal to an analog-to-digital converter for synchronizing the analog-to-digital converter;
receiving, by a receiver, a plurality of radio frequency pulses, wherein each radio frequency pulse is digitized into an in-phase and quadrature sample at a clock edge of the clock signal at the analog-to-digital converter;
storing, by a buffer, each in-phase and quadrature sample digitized by the analog-to-digital converter; and
retrieving and determining, by a correlator, a time of flight of each of the in-phase and quadrature samples.

9. The method of claim 1, wherein the analog-to-digital converter provides real time radio frequency pulse digitization.

10. The method of claim 1, wherein the synthesizing card comprises an oscillator generating a signal that is controlled by a phase-locked loop module.

11. The method of claim 10, wherein the controlled signal generates the clock signal transmitted to the analog-to-digital converter.

12. The method of claim 8, wherein the synthesizing card is integrated into the apparatus including the analog-to-digital converter.

13. The method of claim 6, wherein the plurality of radio frequency pulses correspond to reflected signals from an object at a distance.

14. The method of claim 6, wherein the analog-to-digital converter is hardened to protect against radiation.

15. The method of claim 14, wherein the analog-to-digital converter is hardened to 100 kilorads.

16. The method of claim 15, wherein the buffer is located within a field programmable gate array.

17. A non-transitory machine readable medium having stored thereon machine-readable instructions executable to cause a machine to perform operations comprising:
transmitting, by a synthesizing card, a clock signal to an analog-to-digital converter for synchronizing the analog-to-digital converter;
receiving, by a receiver, a plurality of radio frequency pulses, wherein each radio frequency pulse is digitized into an in-phase and quadrature sample at a clock edge of the clock signal at the analog-to-digital converter;
storing, by a buffer, each in-phase and quadrature sample digitized by the analog-to-digital converter; and
retrieving and determining, by a correlator, a time of flight of each of the in-phase and quadrature samples.

18. The medium of claim 17, wherein the synthesizing card comprises an oscillator generating a signal that is controlled by a phase-locked loop module.

19. The medium of claim 18, wherein the controlled signal generates the clock signal transmitted to the analog-to-digital converter.

20. The medium of claim 17, wherein the synthesizing card is integrated into the apparatus including the analog-to-digital converter.
